(19) United States
(12) Patent Application Publication
(10) Pub. No.: US 2026/0082585 A1
(43) Pub. Date: Mar. 19, 2026

(54) MAGNETORESISTIVE ELEMENT, STORAGE DEVICE, AND ELECTRONIC APPARATUS

(71) Applicant: SONY SEMICONDUCTOR SOLUTIONS CORPORATION, KANAGAWA (JP)

(72) Inventor: MASAKI ENDO, KANAGAWA (JP)

(21) Appl. No.: 19/110,432

(22) PCT Filed: Sep. 12, 2023
(86) PCT No.: PCT/JP2023/033216

§ 371 Date: Mar. 11, 2025

(30) Foreign Application Priority Data
Sep. 20, 2022 (JP) 2022-149182

(51) Int. Cl. H10B 61/00; H10N 50/10

(52) U.S. Cl. CPC H10B 61/20; H10N 50/10

(57) ABSTRACT

A magnetoresistive element according to an embodiment of the present disclosure includes: a laminated body; a storage layer laminated on the laminated body and having a variable magnetization direction; a non-magnetic layer laminated on the storage layer; and a reference layer laminated on the non-magnetic layer and having a fixed magnetization direction, in which the laminated body includes a magnetic layer having a variable magnetization direction, and a non-magnetic metal layer laminated on the magnetic layer.

### FIELD

The present disclosure relates to a magnetoresistive element, a storage device, and an electronic apparatus.

### BACKGROUND

A magnetoresistive random access memory (MRAM) uses a magnetoresistive element (magnetoresistive effect element) as a storage element, and maintains a state by a magnetization state of a ferromagnetic material, and thus, has a non-volatility in which recorded data is maintained even if a power supply is turned off. A basic structure of the magnetoresistive element is a sandwich structure in which a non-magnetic thin film of an insulator is sandwiched between two magnetic layers made of magnetic thin films. This structure is referred to as a magnetic tunnel junction (MTJ).

In the MRAM, magnetization of one magnetic layer (reference layer) of the two magnetic layers is fixed, and magnetization of the other magnetic layer (storage layer) is controlled by an external factor such as a magnetic field or a current. A state in which magnetization directions of the reference layer and the storage layer are parallel to each other is referred to as a parallel state, and a state in which the magnetization directions thereof are antiparallel to each other is referred to as an antiparallel state. Data (“0” or “1”) is stored in a non-volatile manner by rewriting such parallel or antiparallel state of the magnetization directions.

As a next generation write scheme for such an MRAM, for example, attention has been paid to current writing by spin orbit torque (SOT) using spin orbit interaction (see, for example, Patent Literature 1). The writing using the SOT scheme is a method of causing a current to flow through a lower wiring called a spin injection layer (for example, an SOT injection layer) instead of causing a current to flow through an MTJ main body as in a conventional scheme using spin transfer torque, and thus, there is an advantage in that barrier breakdown can be avoided.

### CITATION LIST

### Patent Literature

Patent Literature 1: WO 2019/155957 A

### SUMMARY

### Technical Problem

However, since the amount of spin polarization current (spin Hall angle serving as an index thereof) generated in a spin injection layer is small, a write threshold current density, that is, a write current is large, thereby causing an increase in power consumption.

Therefore, the present disclosure provides a magnetoresistive element, a storage device, and an electronic apparatus that enable reduction in power consumption.

### Solution to Problem

A magnetoresistive element according to an embodiment of the present disclosure includes: a laminated body; a storage layer laminated on the laminated body and having a variable magnetization direction; a non-magnetic layer laminated on the storage layer; and a reference layer laminated on the non-magnetic layer and having a fixed magnetization direction, wherein the laminated body includes a magnetic layer having a variable magnetization direction, and a non-magnetic metal layer laminated on the magnetic layer.

A storage device according to an embodiment of the present disclosure includes: a plurality of magnetoresistive elements, wherein each of the plurality of magnetoresistive elements includes a laminated body, a storage layer laminated on the laminated body and having a variable magnetization direction, a non-magnetic layer laminated on the storage layer, and a reference layer laminated on the non-magnetic layer and having a fixed magnetization direction, and the laminated body includes a magnetic layer having a variable magnetization direction, and a non-magnetic metal layer laminated on the magnetic layer.

An electronic apparatus according to an embodiment of the present disclosure includes: a storage device, wherein the storage device includes a plurality of magnetoresistive elements, each of the plurality of magnetoresistive elements includes a laminated body, a storage layer laminated on the laminated body and having a variable magnetization direction, a non-magnetic layer laminated on the storage layer, and a reference layer laminated on the non-magnetic layer and having a fixed magnetization direction, and the laminated body includes a magnetic layer having a variable magnetization direction, and a non-magnetic metal layer laminated on the magnetic layer.

### BRIEF DESCRIPTION OF DRAWINGS

FIG. 1 is a diagram illustrating a configuration example of a magnetoresistive element according to an embodiment of the present disclosure.

FIG. 2 is a diagram illustrating various effects of a first laminated body according to the embodiment of the present disclosure.

FIG. 3 is a diagram illustrating writing of data “1” to the magnetoresistive element according to the embodiment of the present disclosure.

FIG. 4 is a diagram illustrating writing of data “0” to the magnetoresistive element according to the embodiment of the present disclosure.

FIG. 5 is a diagram illustrating reading of data “1” or “0” from the magnetoresistive element according to the embodiment of the present disclosure.

FIG. 6 is a diagram illustrating writing of data “1” to a magnetoresistive element according to a first modification.

FIG. 7 is a diagram illustrating writing of data “0” to the magnetoresistive element according to the first modification.

FIG. 8 is a diagram illustrating reading of data “1” or “0” from the magnetoresistive element according to the first modification.

FIG. 9 is a diagram illustrating a configuration example of a magnetoresistive element according to a second modification.

FIG. 10 is a diagram illustrating a configuration example of a magnetoresistive element according to a third modification.

FIG. 11 is a diagram illustrating a configuration example of a magnetoresistive element according to a fourth modification.

FIG. 12 is a diagram illustrating a configuration example of a magnetoresistive element according to a fifth modification.

FIG. 13 is a diagram illustrating a configuration example of a magnetoresistive element according to a sixth modification.

FIG. 14 is a diagram illustrating a configuration example of a magnetoresistive element according to a seventh modification.

FIG. 15 is a diagram illustrating a configuration example of a magnetoresistive element according to an eighth modification.

FIG. 16 is a diagram illustrating a configuration example of a magnetoresistive element according to a ninth modification.

FIG. 17 is a diagram illustrating a configuration example of a magnetoresistive element according to a tenth modification.

FIG. 18 is a diagram illustrating a configuration example of a magnetoresistive element according to an eleventh modification.

FIG. 19 is a diagram illustrating a configuration example of a magnetoresistive element according to a twelfth modification.

FIG. 20 is a diagram illustrating a configuration example of a magnetoresistive element according to a thirteenth modification.

FIG. 21 is a diagram illustrating a configuration example of a magnetoresistive element according to a fourteenth modification.

FIG. 22 is a diagram illustrating a configuration example of a storage device according to an application example.

FIG. 23 is a diagram illustrating a configuration example of a memory cell provided in the storage device according to the application example.

FIG. 24 is a diagram illustrating a configuration example of an imaging device according to the application example.

FIG. 25 is a diagram illustrating a configuration example of a distance measurement device according to the application example.

FIG. 26 is a diagram illustrating an appearance example of a game device according to the application example.

FIG. 27 is a diagram illustrating a configuration example of the game device according to the application example.

### DESCRIPTION OF EMBODIMENTS

Hereinafter, embodiments of the present disclosure will be described in detail with reference to the drawings. Note that elements, devices, apparatuses, and the like according to the present disclosure are not limited by the embodiments. Further, the same portions are basically denoted by the same reference signs in the following embodiments, and a repetitive description thereof will be omitted.

Further, one or a plurality of embodiments (including examples and modifications) described below can each be implemented independently. Meanwhile, at least some of the plurality of embodiments to be described hereinafter may be implemented appropriately in combination with at least some of other embodiments. The plurality of embodiments may include novel features different from each other. Therefore, the plurality of embodiments can contribute to achieving mutually different objects or solutions to problems, and can exhibit mutually different effects. Note that the effects of the respective embodiments are merely examples and are not limited, and additional effects may be present.

Further, the drawings referred to in the following description are drawings for facilitating the description and understanding of an embodiment of the present disclosure, and shapes, dimensions, ratios, and the like illustrated in the drawings are sometimes different from actual ones for the sake of clarity. Furthermore, an element and the like illustrated in the drawings can be appropriately modified in design in consideration of the following description and known techniques. Further, in the following description, for example, a vertical direction of a laminate structure of the element and the like corresponds to a relative direction in a case where a surface of a substrate on which the element is provided is facing upward, and is sometimes different from the vertical direction according to actual gravitational acceleration.

The present disclosure will be described according to the following item order.
1. Embodiment
1-1. Configuration Example of Magnetoresistive Element
1-2. Various Effects of First Laminated Body
1-3. Write Scheme and Read Scheme
1-4. Modification of Magnetoresistive Element
1-4-1. First Modification
1-4-2. Second Modification
1-4-3. Third Modification
1-4-4. Fourth Modification
1-4-5. Fifth Modification
1-4-6. Sixth Modification
1-4-7. Seventh Modification
1-4-8. Eighth Modification
1-4-9. Ninth Modification
1-4-10. Tenth Modification
1-4-11. Eleventh Modification
1-4-12. Twelfth Modification
1-4-13. Thirteenth Modification
1-4-14. Fourteenth Modification
1-5. Action and Effect
2. Storage Device (Application Example)
3. Electronic Apparatus (Application Example)
3-1. Imaging Device
3-2. Distance Measurement Device
3-3. Game Device
4. Other Embodiments
5. Appendix

### 1. Embodiment

### 1-1. Configuration Example of Magnetoresistive Element

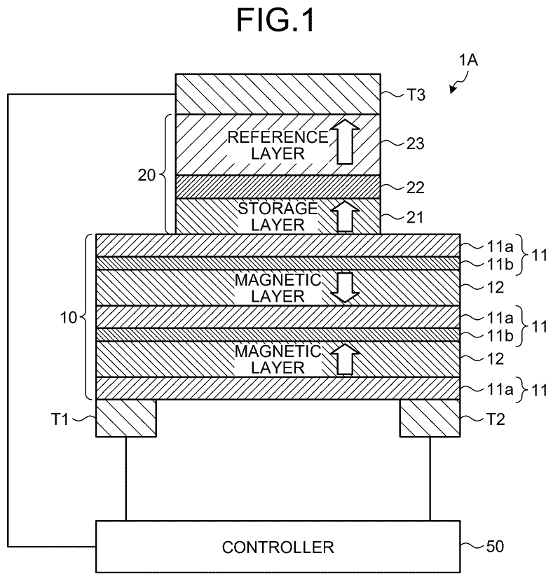

A configuration example of a magnetoresistive element 1A according to the present embodiment will be described with reference to FIG. 1. FIG. 1 is a diagram illustrating a configuration example of the magnetoresistive element 1A according to the present embodiment.

As illustrated in FIG. 1, the magnetoresistive element 1A according to the present embodiment includes a first laminated body 10, a second laminated body 20, and a plurality of terminals T1, T2, and T3. The magnetoresistive element 1A is connected to a controller 50 via the terminals T1, T2, and T3. For example, the terminal Tl is provided on one of both ends of a lower surface of the first laminated body 10, the terminal T2 is provided on the other of both ends of the lower surface of the first laminated body 10, and the terminal T3 is provided on an upper surface of the second laminated body 20.

The controller 50 is a control device that controls voltage application for causing a current to flow through the magnetoresistive element 1A. The controller 50 is realized by, for example, an integrated circuit such as a field programmable gate array (FPGA) or an application specific integrated circuit (ASIC). Note that the controller 50 may be realized by, for example, a processor such as a central processing unit (CPU) or a micro processing unit (MPU) that executes various programs using a random access memory (RAM) or the like as a work area, and is not particularly limited.

The first laminated body 10 includes a plurality of non-magnetic metal layers 11 and a plurality of magnetic layers 12. The first laminated body 10 is formed in, for example, a rectangular parallelepiped shape. Note that the shape of the first laminated body 10 is not particularly limited, and the first laminated body 10 may be formed in, for example, a cubic shape or a cylindrical shape.

The non-magnetic metal layers 11 and the magnetic layers 12 are alternately laminated. Therefore, the non-magnetic metal layer 11 as an upper layer (upper portion), the non-magnetic metal layer 11 as an intermediate layer (intermediate portion), and the non-magnetic metal layer 11 as a lower layer (lower portion) exist, and the magnetic layer 12 exists between the layers. Each of the non-magnetic metal layers 11 as the upper layer and the intermediate layer includes both a first spin injection layer 11a and a second spin injection layer 11b. Note that, in the non-magnetic metal layer 11, the first spin injection layer 11a is located on the upper layer side, that is, on the storage layer 21 side of the second spin injection layer 11b. The lower non-magnetic metal layer 11 includes only the first spin injection layer 11a.

The first spin injection layer 11a is an injection layer (for example, an SOT injection layer) having a spin Hall angle of a first sign (for example, plus). The first spin injection layer 11a can be made of, for example, a heavy metal such as Pt and Ru. In addition, the second spin injection layer 11b is an injection layer (for example, an SOT injection layer) having a spin Hall angle of a second sign (for example, minus) different from the first sign. The second spin injection layer 11b can be made of, for example, a heavy metal such as Ta, W, and Ir. When the first sign is plus, the second sign is minus, and when the first sign is minus, the second sign is plus.

Here, a spin Hall angle θ_{SH} is defined by a relational expression of θ_{SH}=Js/Jc. Js is a spin current density and Jc is a current density. A sign (for example, plus or minus) of the spin Hall angle depends on a material. For example, an upward direction of a spin (for example, a spin-polarized electron) is set to plus, and a downward direction of the spin is set to minus. The settings may be reversed.

Such a first laminated body 10 functions as a spin injection layer and a secondary storage layer. Specifically, each of the first spin injection layer 11a and the second spin injection layer 11b in the first laminated body 10 functions as a spin injection layer for injecting spin into the storage layer 21 and each magnetic layer 12. In addition, each of the magnetic layers 12 in the first laminated body 10 functions as a secondary storage layer that assists data storage of the storage layer 21, that is a primary storage layer, by a change in its own magnetization direction. In addition, spin conversion efficiency can be improved by providing the magnetic layer 12 in the first laminated body 10, and spin conversion efficiency can be further improved by hybrid of the magnetic layer 12 and the spin injection layers 11a and 11b made of heavy metal.

Note that the first laminated body 10 is formed, for example, such that antiferromagnetic coupling occurs between the respective magnetic layers 12. That is, the respective magnetic layers 12 are antiferromagnetically coupled to each other, and are coupled with opposite polarities due to the antiferromagnetic coupling. By using antiferromagnetic coupling between the magnetic layers 12, a write current can be reduced from a relationship of a direction of torque. The antiferromagnetic coupling refers to, for example, indirect coupling between ferromagnetic layers in which adjacent ferromagnetic layers or multiple ferromagnetic layers have magnetization facing opposite directions to each other.

The second laminated body 20 includes a storage layer 21, a non-magnetic layer 22, and a reference layer 23. The second laminated body 20 is formed in, for example, a rectangular parallelepiped shape smaller than that of the first laminated body 10, and is provided at the center of the upper surface of the first laminated body 10. Note that the shape and arrangement of the second laminated body 20 are not particularly limited, and for example, the second laminated body 20 may be formed in a cubic shape or a cylindrical shape smaller than that of the first laminated body 10, or may be provided at a position other than the center of the upper surface of the first laminated body 10 by being shifted from the center thereof.

The storage layer 21 is a layer having magnetic anisotropy and a variable magnetization direction. A state where the magnetization direction of the storage layer 21 and the magnetization direction of the reference layer 23 are identical and a state where the magnetization direction of the storage layer 21 and the magnetization direction of the reference layer 23 are different are referred to as a parallel state and an antiparallel state, respectively. The magnetoresistive element 1A is in a low resistance state in the parallel state, and is in a high resistance state in the antiparallel state. Note that the magnetization direction of the storage layer 21 can be changed by applying a voltage to the magnetoresistive element 1A.

Further, the storage layer 21 can be made of cobalt iron (CoFe), cobalt iron boron (CoFeB), Fe, iron boride (FeB), or the like. Further, it is also possible to adopt a configuration including a transition metal (Hf, Ta, W, Re, Ir, Pt, Au, Zr, Nb, Mo, Ru, Rh, Pd, Ag, Ti, V, Cr, Mn, Ni, or Cu) or the like. In addition, a nitride or an oxide may be included. Further, iridium (Ir) or osmium (Os) can be used as a material that induces a proximity magnetic moment to the magnetic material. Note that a heavy metal can also be added to the storage layer 21 to improve the voltage-controlled magnetic anisotropy effect.

Furthermore, the storage layer 21 may have a laminate structure in which a plurality of ferromagnetic layers are laminated with a non-magnetic layer interposed therebetween. At this time, two ferromagnetic layers adjacent to each other with the non-magnetic layer interposed therebetween may be exchange-coupled. The non-magnetic layer can be made of Mg, Al, Ti, Si, Zn, Zr, Hf, Ta, Bi, Cr, Ga, La, Gd, Sr, Ba, W, Re, Ir, Pt, Au, Nb, Mo, Ru, Rh, Pd, Ag, V, Mn, Ni, Cu, or the like.

The non-magnetic layer 22 is made of an insulator (insulating layer) such as Mgo, and functions as a tunnel barrier layer. The tunnel barrier layer is sandwiched between the storage layer 21 and the reference layer 23, forms a magnetic tunnel junction (MTJ), and exhibits a tunnel magnetoresistance (TMR) effect depending on a relative angle of magnetization between the storage layer 21 and the reference layer 23. In addition, the tunnel barrier layer has a function of controlling the magnetization direction by causing a spin polarization current to flow through the storage layer 21. In addition, by increasing a tunnel barrier thickness, that is, by increasing resistance, it is also possible to apply an electric field to impart a voltage control magnetic anisotropy effect. The tunnel barrier layer can be made of an oxide of at least one element selected from the group of Mg, Al, Ti, Si, Zn, Zr, Hf, Ta, Bi, Cr, Ga, La, Gd, Sr, and Ba, or a nitride of at least one element selected from the group of Mg, Al, Ti, Si, Zn, Zr, Hf, Ta, Bi, Cr, Ga, La, Gd, Sr, and Ba. Further, it can also be configured using an insulator such as MgF2, CaF, SrTiO2, AlLaO3, or AlNO, a dielectric, and a semiconductor. It is also possible to have a structure in which these layers are laminated. Note that the non-magnetic layer 22 may include, for example, a conductor, and here, forms a giant magnetoresistance (GMR) element structure.

The reference layer 23 is a magnetization fixed layer having magnetic anisotropy and a fixed (invariable) magnetization direction. The reference layer 23 can be made of, for example, CoFeB, a CoFeC alloy, a NiFeB alloy, a NiFeC alloy, or the like. Furthermore, the reference layer 23 can have a laminated ferri-pin structure in which a plurality of ferromagnetic layers are laminated with a non-magnetic layer interposed therebetween. As a material of the ferromagnetic layer constituting the reference layer 23 having the laminated ferri-pin structure, a first layer using Co, CoFe, CoFeB, or the like, and a second layer which is an artificial alternately laminated film or an alloy composed of at least one element selected from an element group of Co, Fe, and Ni and at least one element selected from an element group of Ir, Pt, Pd, Cr, V, lanthanoid, and actinoid are included. Furthermore, as a material of the non-magnetic layer constituting the reference layer 23, Ru, Re, Ir, Os, or the like can be used. As the reference layer 23, a configuration in which the first layer, the non-magnetic layer, and the second layer are repeatedly laminated may be used.

Further, the reference layer 23 can be configured such that the orientation of magnetization is fixed by utilizing antiferromagnetic coupling between an antiferromagnetic layer and a ferromagnetic layer. Examples of a material of the antiferromagnetic layer can include magnetic materials such as a FeMn alloy, a PtMn alloy, a PtCrMn alloy, a NiMn alloy, an IrMn alloy, Nio, and Fe2O3. Further, a non-magnetic element such as Ag, Cu, Au, Al, Si, Bi, Ta, B, C, O, N, Pd, Pt, Zr, Hf, Ir, W, Mo, or Nb can be added to these magnetic materials.

The terminal T1 and the terminal T2 configure an input terminal pair that provides a write current that changes the magnetization state of the storage layer 21. The terminal T1 and the terminal T2 are provided on a surface of the first laminated body 10, in which the surface is opposite to the storage layer 21, that is, the lower surface of the first laminated body 10, and are electrically connected to the first laminated body 10. The terminal T1 and the terminal T2 are provided at intervals at positions sandwiching the storage layer 21 in plan view parallel to an in-plane direction orthogonal to the vertical direction (lamination direction) of the first laminated body 10. In the example of FIG. 1, the terminal T1 and the terminal T2 are disposed at both end portions of the lower surface of the first laminated body 10. The controller 50 is connected to the terminal T1 and the terminal T2 via a wiring. Voltages are respectively applied from the controller 50 to the terminal T1 and the terminal T2. When a certain voltage is applied to the terminal T1 or the terminal T2, that is, when a voltage is applied to one terminal, a write current flows in the in-plane direction of the first laminated body 10 from the one terminal toward the other terminal. As a result, the spin-polarized current flows into the storage layer 21, and the magnetization state of the storage layer 21 changes. Torque acting on the storage layer 21 here is referred to as spin orbit torque. Note that the direction in which the write current flows is different in a case where a voltage is applied to the terminal T1 and a case where a voltage is applied to the terminal T2. Therefore, the magnetization direction of the storage layer 21 with respect to the reference layer 23 can be either the parallel state or the antiparallel state depending on the direction of the write current.

The terminal T3 configures an output terminal pair with one (or both) of the terminal T1 and the terminal T2, in which the pair extracts a read current corresponding to the magnetization state of the storage layer 21. The terminal T3 is provided on a surface of the second laminated body 20, in which the surface is opposite to the storage layer 21, that is, the upper surface of the second laminated body 20, and is electrically connected to the second laminated body 20. When determining the magnetization state of the storage layer 21, the output terminal pair applies, for example, a voltage between the terminal Tl and the terminal T3, and causes a read current to flow through a path from the lower surface of the first laminated body 10 to the upper surface of the second laminated body 20. For example, the magnitude of resistance (for example, tunnel resistance) between the storage layer 21 and the reference layer 23 is determined from the applied voltage and the read current, and the magnetization state (parallel state or antiparallel state) of the storage layer 21 is obtained. The resistance between the storage layer 21 and the reference layer 23 changes to a relatively high resistance state and a relatively low resistance state according to the magnetization state of the storage layer 21.

The above-described various layers can be produced by, for example, a physical vapor deposition (PVD) method typified by a sputtering method, an ion beam deposition method, and a vacuum vapor deposition method, and a chemical vapor deposition (CVD) method typified by an atomic layer deposition (ALD) method. Further, patterning of these layers can be performed by a reactive ion etching (RIE) method or an ion milling method. It is preferable to form the various layers consecutively in a vacuum apparatus, and it is preferable to perform patterning thereafter.

### 1-2. Various Effects of First Laminated Body

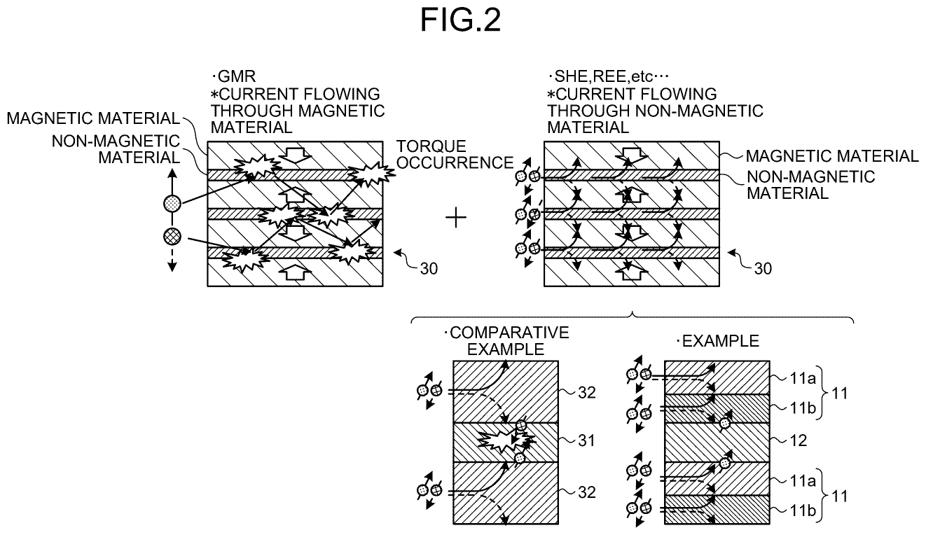

Various effects of the first laminated body 10 according to the present embodiment will be described with reference to FIG. 2. FIG. 2 is a diagram illustrating various effects of the first laminated body 10 according to the present embodiment. In the following description, a spin-polarized electron, that is, an electron spin-polarized upward is referred to as an upward spin, and an electron spin-polarized downward is referred to as a downward spin as necessary.

As illustrated in FIG. 2, a laminate structure body 30 is formed by alternately laminating a magnetic material and a non-magnetic material. The laminate structure body 30 has a giant magnetoresistance (GMR) effect, and further has effects such as spin Hall effect (SHE) and Rashba-Edelstein effect (REE). That is, the laminate structure body 30, for example, the first laminated body 10 is configured to have such various effects.

In the GMR effect, when the current flows along the in-plane direction of the laminate structure body 30, naturally, the current also flows through the magnetic material. In response thereto, the upward spin and the downward spin move in the magnetic material, and for example, the upward spin and the downward spin move while being scattered at the interface by the magnetic material adjacent to the moving magnetic material. Specifically, the upward spin moves while being strongly scattered at the interface by the magnetic material in which the magnetization is directed downward, and the downward spin moves while being strongly scattered at the interface by the magnetic material in which the magnetization is directed upward. As a result, torque corresponding to the upward spin or the downward spin is generated, and the magnetization direction of the magnetic material changes.

In addition, in the effect of SHE, REE, or the like, when the current flows along the in-plane direction of the laminate structure body 30, naturally, the current also flows through the non-magnetic material. In response thereto, the upward spin and the downward spin move in the non-magnetic material. Here, force acts on each electron in an outer product direction of the conduction direction (direction opposite to the current) and the spin polarization direction. Therefore, for example, when viewed in the in-plane direction of the laminate structure body and from the current direction, spins that are polarized 90 degrees clockwise are scattered and moved upward, and spins that are polarized 90 degrees counterclockwise are scattered and moved downward. The spins are referred to as the upward spin and the downward spin in the SHE and REE effects, respectively. As a result, one or both of the upward spin and the downward spin are accumulated in the magnetic material.

Meanwhile, in a comparative example, a magnetic layer 31 is sandwiched by non-magnetic metal layers 32 each including one layer. Here, the downward spin enters the magnetic layer 31 from the upper non-magnetic metal layer 32, and the upward spin enters the magnetic layer 31 from the lower non-magnetic metal layer 32. Since the downward spin and the upward spin have different signs of spin Hall angles, the spins cancel each other in the magnetic layer 31, and the spin orbit torque (SOT) deteriorates.

On the other hand, in the example (the present embodiment), the magnetic layer 12 is sandwiched between the non-magnetic metal layers 11 each including two layers. As described above, the non-magnetic metal layer 11 includes both the upper first spin injection layer 11a and the lower second spin injection layer 11b. The upper first spin injection layer 11a scatters and moves the upward spin in the upward direction and scatters and moves the downward spin in the downward direction. Meanwhile, since the sign of the spin Hall angle of the lower second spin injection layer 11b is different from that of the first spin injection layer 11a, the lower second spin injection layer 11b scatters and moves the downward spin in the upward direction and scatters and moves the upward spin in the downward direction.

Specifically, the magnetic layer 12 is sandwiched between the second spin injection layer 11b and the first spin injection layer 11a. Here, the upward spin from the second spin injection layer 11b enters the magnetic layer 12, and the upward spin from the first spin injection layer 11a also enters the magnetic layer 12. Since the upward spins have the same sign of the spin Hall angle, the spins do not cancel each other in the magnetic layer 12, and the spin orbit torque can be improved. Note that a spin current carrying a spin angular momentum is generated perpendicularly to the direction of the current. When the spin current flows into the magnetic material, torque is generated, and the magnetization direction of the magnetic material can be reversed.

Effects such as an anisotropic magneto resistance (AMR) effect, an anomalous Hall effect (AHE), and a planar Hall effect (PHE) may contribute to such spin current generation. Here, the first laminated body 10 and the second laminated body 20 are configured to have such effects. In addition, spin transfer torque (STT) may be combined with spin orbit torque (SOT). Note that the sign of the current (direction of the current) and the direction and magnitude in which the spin (upward spin or downward spin) is scattered are determined by the sign of the spin Hall angle, and may be opposite to those described above.

As described above, writing efficiency can be improved by utilizing the magnetic material having higher spin conversion efficiency than that of the non-magnetic material for the first laminated body 10. Furthermore, by suppressing cancellation between the upward spins or between the downward spins, it is possible to suppress deterioration in spin orbit torque. In addition, by using the first laminated body 10, the thickness of the first laminated body 10 is large as compared with a case where the spin injection layer is formed to be extremely thin (for example, several nm), and it is possible to secure or improve the yield. For example, tolerance to variations in trench depth is improved.

### 1-3. Write Scheme and Read Scheme

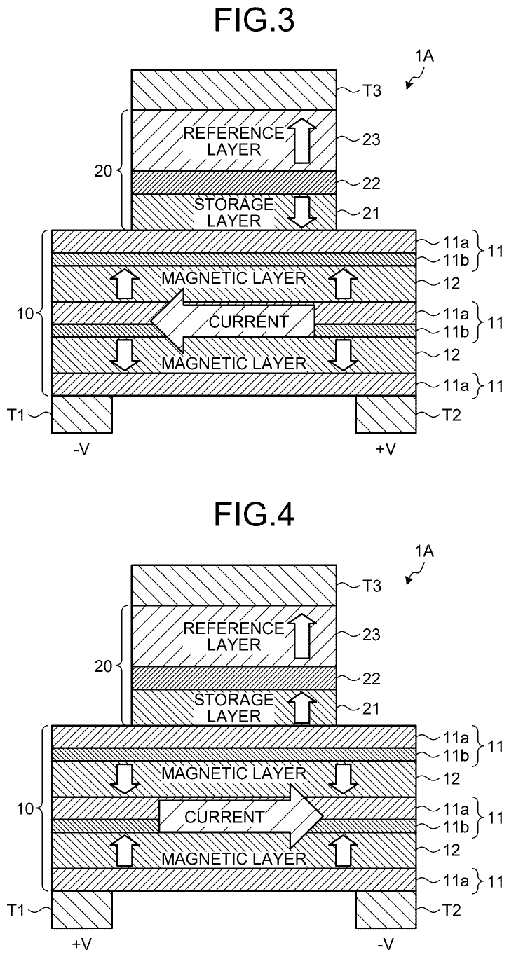

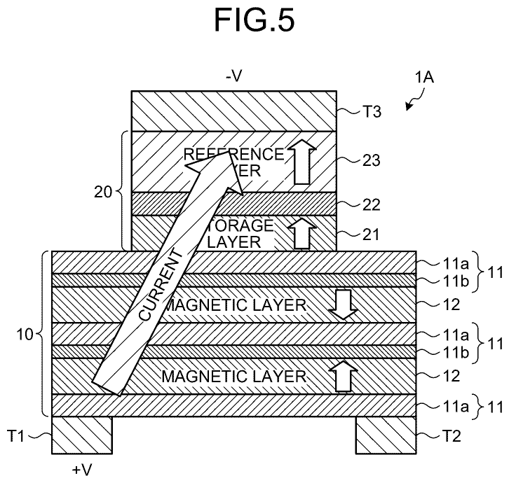

A write scheme and a read scheme according to the present embodiment will be described with reference to FIGS. 3 to 5. FIG. 3 is a diagram illustrating writing of data “1” to the magnetoresistive element 1A according to the present embodiment. FIG. 4 is a diagram illustrating writing of data “0” to the magnetoresistive element 1A according to the present embodiment. FIG. 5 is a diagram illustrating reading of data “1” or data “0” from the magnetoresistive element 1A according to the present embodiment.

An operation when the magnetoresistive element 1A is used as a memory of one-bit data (data “1” or “0”) will be described. One-bit data of “0” and “1” is allocated in advance to the magnetization state, that is, the resistance state of the storage layer 21. For example, “1” is allocated to the high resistance state (antiparallel state) of the storage layer 21 and “0” is allocated to the low resistance state (parallel state) of the storage layer 21.

As illustrated in FIG. 3, in the writing of the data “1” to the magnetoresistive element 1A, voltages are respectively applied to the terminal T1 and the terminal T2 of the magnetoresistive element 1A. For example, when voltages (−V, +V) are respectively applied to the terminal T1 and the terminal T2, a write current (in-plane current) flowing from the terminal T2 side to the terminal T1 side flows through the first laminated body 10. In response thereto, for example, the downward spin enters the storage layer 21 from the upper first spin injection layer 11a, the downward spin enters the upper magnetic layer 12 from the upper second spin injection layer 11b and the intermediate first spin injection layer 11a, and the downward spin enters the lower magnetic layer 12 from the lower second spin injection layer 11b and the lower first spin injection layer 11a. That is, only the downward spins respectively enter the storage layer 21 and each magnetic layer 12, and spin orbit torque (SOT) due to the downward spins acts on the magnetization of the storage layer 21 and each magnetic layer 12. Furthermore, torque due to the GMR effect is generated, and acts on the magnetization of each magnetic layer 12. By such actions, the magnetization of the storage layer 21 becomes the antiparallel state facing the downward direction opposite to the magnetization direction of the reference layer 23. As a result, the magnetoresistive element 1A becomes the high resistance state, and the data becomes “1”.

As illustrated in FIG. 4, even in the writing of the data “0” to the magnetoresistive element 1A, voltages are respectively applied to the terminal T1 and the terminal T2 of the magnetoresistive element 1A. For example, when voltages (+V, −V) opposite to the above-described voltages are respectively applied to the terminal T1 and the terminal T2, a write current (in-plane current) flowing from the terminal T1 side to the terminal T2 side flows through the first laminated body 10. In response thereto, for example, the upward spin enters the storage layer 21 from the upper first spin injection layer 11a, the upward spin enters the upper magnetic layer 12 from the upper second spin injection layer 11b and the intermediate first spin injection layer 11a, and the upward spin enters the lower magnetic layer 12 from the lower second spin injection layer 11b and the lower first spin injection layer 11a. That is, only the upward spins respectively enter the storage layer 21 and each magnetic layer 12, and the spin orbit torque (SOT) due to the upward spins acts on the magnetization of the storage layer 21 and each magnetic layer 12. Furthermore, torque due to the GMR effect is generated, and acts on the magnetization of each magnetic layer 12. By such actions, the magnetization of the storage layer 21 becomes the parallel state facing the upward direction same as the magnetization direction of the reference layer 23. As a result, the magnetoresistive element 1A becomes the low resistance state, and the data becomes “0”.

As illustrated in FIG. 5, when data “1” or “0” is read from the magnetoresistive element 1A, a predetermined voltage is applied between the terminal T1 and the terminal T3. From the magnitude of the applied voltage and the read current, the resistance state of a current path (path) passing through the first laminated body 10 and the second laminated body 20 is determined by the controller 50, and one-bit data is specified from the resistance state. Note that the read current only needs to flow in a direction penetrating a magnetic tunnel junction including the storage layer 21, the non-magnetic layer 22, and the reference layer 23, and thus may flow from the storage layer 21 toward the reference layer 23 or vice versa. More preferably, a direction in which a current flows from the reference layer 23 toward the storage layer 21 is used for reading.

In the example of FIG. 5, since the magnetization direction of the storage layer 21 is directed upward and is the same as the magnetization direction of the reference layer 23, the storage layer 21 is in the parallel state. The magnetoresistive element 1A in the parallel state is in a low resistance state in which the resistance of the current path between the storage layer 21 and the reference layer 23 is relatively small. Therefore, the read current becomes relatively large. On the other hand, the magnetoresistive element 1A in the antiparallel state is in a high resistance state in which the resistance of the current path between the storage layer 21 and the reference layer 23 is relatively large. Therefore, the read current becomes relatively small.

In the above-described writing, when the same data as the data stored in the magnetoresistive element 1A is written, the data is not rewritten even if the write current flows in the magnetoresistive element 1A, and when data different from the data stored in the magnetoresistive element 1A is written, the data is rewritten.

In addition, a relationship between the direction of the write current and the directions of the spin current and the spin orbit torque is an example, and the directions of the spin current and the spin orbit torque relative to the direction of the write current is variable depending on materials to be used for the first laminated body 10, the storage layer 21, the non-magnetic layer 22, and the like and a combination thereof. Therefore, the direction of the write current with respect to the data to be stored is determined based on the materials to be used for the first laminated body 10, the storage layer 21, and the non-magnetic layer 22 and the combination thereof.

In addition, although the spin Hall effect is an origin of the spin orbit torque, an origin of the spin orbit torque (SOT) is also derived from other effects as described above. For example, in the case of Rashba-Edelstein effect (REE), a Rashba effective magnetic field acts on electrons flowing through the interface between the first laminated body 10 and the storage layer 21 to accumulate polarization spins, which act on the magnetization of the storage layer 21 to induce magnetization reversal. In any effect, since the magnetization direction of the storage layer 21 is maintained even after the write current becomes 0, the data is stored in the magnetoresistive element 1A in a non-volatile manner.

In addition, when writing data in the magnetoresistive element 1A, a write current (for example, a pulsed write current) is caused to flow through the first laminated body 10 using the terminal T1 and the terminal T2, but the write current may flow only through the first laminated body 10 or may flow through both the first laminated body 10 and the storage layer 21. When the magnetization reversal of the storage layer 21 is induced by the spin Hall effect, it is necessary to introduce a current to at least the first laminated body 10, and here, the write current is caused to flow through at least the first laminated body 10. In addition, when the magnetization reversal is induced by REE, it is necessary to introduce a current to the laminated film interface, and here, the write current is caused to flow through both the first laminated body 10 and the storage layer 21. Note that, in the configuration in which the storage layer 21 is directly formed on the surface of the first laminated body 10, since each of the first laminated body 10 and the storage layer 21 is a conductor, when a current flows through the first laminated body 10, a current also flows through the storage layer 21, and of course, a current also flows through the interface therebetween.

### 1-4. Modification of Magnetoresistive Element

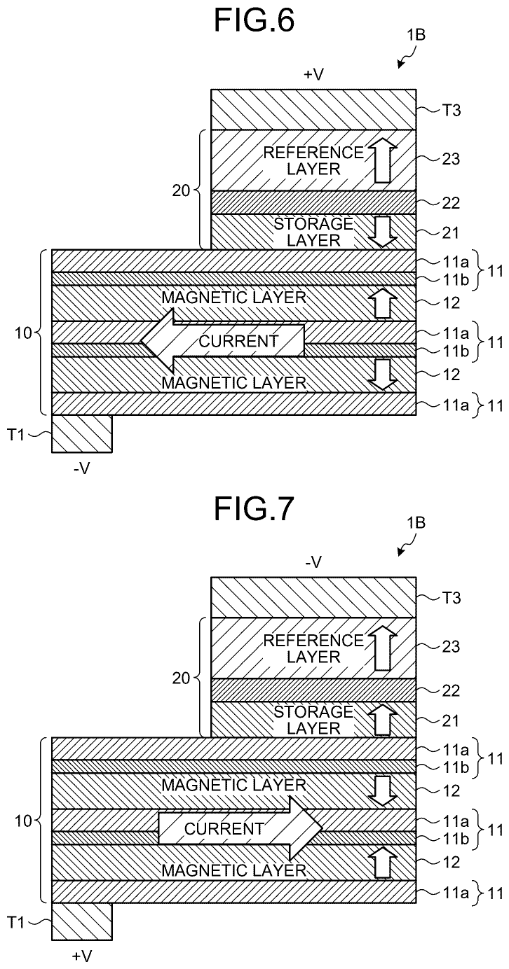

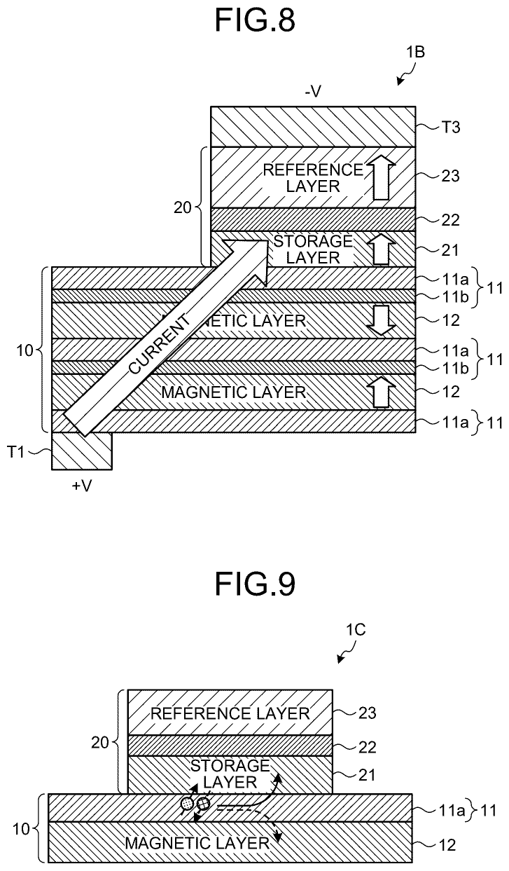

First to fourteenth modifications of magnetoresistive elements 1B to 1O according to the embodiment will be described with reference to FIGS. 6 to 21. FIG. 6 is a diagram illustrating writing of data “1” to the magnetoresistive element 1B according to the first modification. FIG. 7 is a diagram illustrating writing of data “0” to the magnetoresistive element 1B according to the first modification. FIG. 8 is a diagram illustrating reading of data “1” or “0” from the magnetoresistive element 1B according to the first modification. FIGS. 9 to 21 are diagrams illustrating configuration examples of the magnetoresistive elements (the magnetoresistive elements 1C to 1O) according to the modifications (the second to fourteenth modifications). Note that, in the examples of FIGS. 9 to 21, the terminals T1, T2, and T3 are omitted.

### 1-4-1. First Modification

As illustrated in FIG. 6, the second laminated body 20 of the magnetoresistive element 1B according to the first modification is provided at the end portion of the upper surface of the first laminated body 10 while being shifted in the right direction from the center of the upper surface of the first laminated body 10. Furthermore, the magnetoresistive element 1B according to the first modification does not include the terminal T2 according to the first embodiment, but includes only the terminal T1 and the terminal T3.

In such a configuration, as illustrated in FIG. 6, in the writing of the data “1” to the magnetoresistive element 1B, voltages are respectively applied to the terminal T1 and the terminal T3 of the magnetoresistive element 1B. For example, when voltages (−V, +V) are respectively applied to the terminal T1 and the terminal T3, a write current (in-plane current) flowing from the terminal T3 side to the terminal T1 side flows through the first laminated body 10. The subsequent write operation is similar to that in the above-described embodiment.

As illustrated in FIG. 7, even in the writing of the data “0” to the magnetoresistive element 1B, voltages are respectively applied to the terminal T1 and the terminal T3 of the magnetoresistive element 1B. For example, when voltages (+V, −V) opposite to the above-described voltages are respectively applied to the terminal T1 and the terminal T3, a write current (in-plane current) flowing from the terminal T1 side to the terminal T3 side flows through the first laminated body 10. The subsequent write operation is similar to that in the above-described embodiment.

As illustrated in FIG. 8, when data “1” or “0” is read from the magnetoresistive element 1B, a predetermined voltage is applied between the terminal T1 and the terminal T3. From the magnitude of the applied voltage and the read current, the resistance state of the current path passing through the first laminated body 10 and the second laminated body 20 is determined by the controller 50, and one-bit data is specified from the resistance state.

In the first modification and the above-described embodiment, the storage layer 21 is laminated on a part of the upper surface of the first laminated body 10, but the present invention is not limited thereto, and the storage layer 21 may be laminated on the entire upper surface of the first laminated body 10. According to such configuration, the magnetoresistive element 1A can be easily manufactured. Further, in the first modification, the second laminated body 20 is laminated at a position shifted in the right direction (in the drawing) from the center of the upper surface of the first laminated body 10, but the second laminated body 20 may be laminated at a position shifted in the opposite left direction.

### 1-4-2. Second Modification

As illustrated in FIG. 9, the magnetoresistive element 1C according to the second modification includes a first laminated body 10 and the second laminated body 20 according to the above-described embodiment. The first laminated body 10 includes the non-magnetic metal layer 11 and the magnetic layer 12 according to the above-described embodiment. The non-magnetic metal layer 11 includes only the first spin injection layer 11a.

In the magnetoresistive element 1C, an upward spin or a downward spin enters the storage layer 21 or the magnetic layer 12 according to a direction of a current (a direction in which a current flows). Note that, when the upward spin enters the storage layer 21, the downward spin enters the magnetic layer 12, and when the downward spin enters the storage layer 21, the upward spin enters the magnetic layer 12. The spin orbit torque due to the upward spin or the downward spin acts on the magnetization of the magnetic layer 12 and the magnetization of the storage layer 21. Furthermore, torque is generated by the GMR effect, and the torque acts on the magnetic layer 12. By such actions, the magnetization direction of the magnetic layer 12 and the magnetization direction of the storage layer 21 change.

### 1-4-3. Third Modification

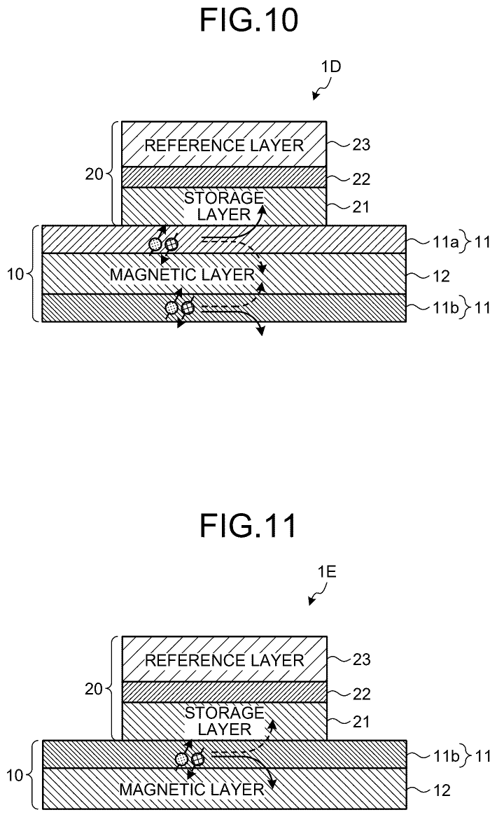

As illustrated in FIG. 10, the magnetoresistive element 1D according to the third modification includes a first laminated body 10 and the second laminated body 20 according to the above-described embodiment. The first laminated body 10 includes an upper non-magnetic metal layer 11, the magnetic layer 12 according to the above-described embodiment, and a lower non-magnetic metal layer 11. The upper non-magnetic metal layer 11 includes only the first spin injection layer 11a. The lower non-magnetic metal layer 11 includes only the second spin injection layer 11b. Note that the magnetic layer 12 is sandwiched between the first spin injection layer 11a and the second spin injection layer 11b.

In the magnetoresistive element 1D, an upward spin or a downward spin enters the storage layer 21 or the magnetic layer 12 according to the direction of the current. The upward spin or downward spin enters the storage layer 21 from the upper first spin injection layer 11a, and the upward spin or the downward spin enters the magnetic layer 12 from the upper first spin injection layer 11a and the lower second spin injection layer 11b. Note that, when the upward spin enters the storage layer 21, the downward spin enters the magnetic layer 12, and when the downward spin enters the storage layer 21, the upward spin enters the magnetic layer 12. The spin orbit torque due to the upward spin or the downward spin acts on the magnetization of the magnetic layer 12 and the magnetization of the storage layer 21. Furthermore, torque is generated by the GMR effect, and the torque acts on the magnetic layer 12. By such actions, the magnetization direction of the magnetic layer 12 and the magnetization direction of the storage layer 21 change.

### 1-4-4. Fourth Modification

As illustrated in FIG. 11, the magnetoresistive element 1E according to the fourth modification includes a first laminated body 10 and the second laminated body 20 according to the above-described embodiment. The first laminated body 10 includes the non-magnetic metal layer 11 and the magnetic layer 12 according to the above-described embodiment. The non-magnetic metal layer 11 includes only the second spin injection layer 11b.

In the magnetoresistive element 1E, an upward spin or a downward spin enters the storage layer 21 or the magnetic layer 12 according to the direction of the current. Note that, when the upward spin enters the storage layer 21, the downward spin enters the magnetic layer 12, and when the downward spin enters the storage layer 21, the upward spin enters the magnetic layer 12. The spin orbit torque due to the upward spin or the downward spin acts on the magnetization of the magnetic layer 12 and the magnetization of the storage layer 21. Furthermore, torque is generated by the GMR effect, and the torque acts on the magnetic layer 12. By such actions, the magnetization direction of the magnetic layer 12 and the magnetization direction of the storage layer 21 change.

### 1-4-5. Fifth Modification

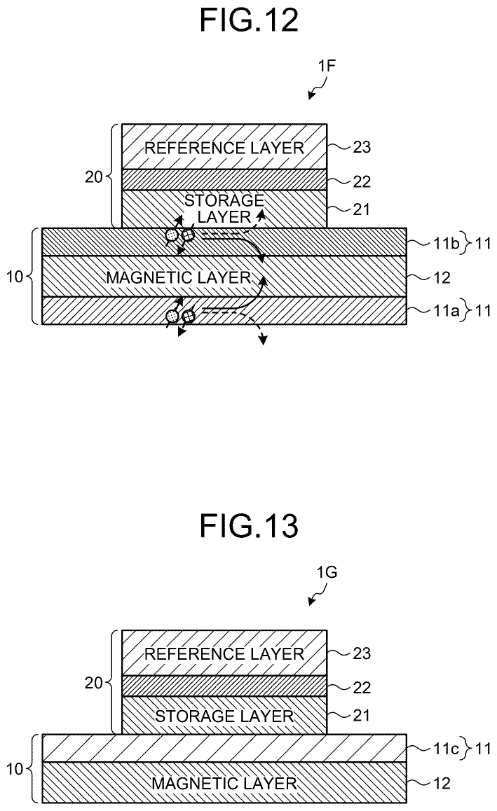

As illustrated in FIG. 12, the magnetoresistive element 1F according to the fifth modification includes a first laminated body 10 and the second laminated body 20 according to the above-described embodiment. The first laminated body 10 includes an upper non-magnetic metal layer 11, the magnetic layer 12 according to the above-described embodiment, and a lower non-magnetic metal layer 11. The upper non-magnetic metal layer 11 includes only the second spin injection layer 11b. The lower non-magnetic metal layer 11 includes only the first spin injection layer 11a. Note that the magnetic layer 12 is sandwiched between the second spin injection layer 11b and the first spin injection layer 11a.

In the magnetoresistive element 1F, an upward spin or a downward spin enters the storage layer 21 or the magnetic layer 12 according to the direction of the current. The upward spin or downward spin enters the storage layer 21 from the upper second spin injection layer 11b, and the upward spin or the downward spin enters the magnetic layer 12 from the upper second spin injection layer 11b and the lower first spin injection layer 11a. Note that, when the upward spin enters the storage layer 21, the downward spin enters the magnetic layer 12, and when the downward spin enters the storage layer 21, the upward spin enters the magnetic layer 12. The spin orbit torque due to the upward spin or the downward spin acts on the magnetization of the magnetic layer 12 and the magnetization of the storage layer 21. Furthermore, torque is generated by the GMR effect, and the torque acts on the magnetic layer 12. By such actions, the magnetization direction of the magnetic layer 12 and the magnetization direction of the storage layer 21 change.

### 1-4-6. Sixth Modification

As illustrated in FIG. 13, the magnetoresistive element 1G according to the sixth modification includes a first laminated body 10 and the second laminated body 20 according to the above-described embodiment. The first laminated body 10 includes the non-magnetic metal layer 11 and the magnetic layer 12 according to the above-described embodiment. The non-magnetic metal layer 11 includes not a spin injection layer but only a metal layer (non-spin-injection metal layer) 11c that does not inject a spin into the storage layer 21. The metal layer 11c is made of, for example, a heavy metal such as Cu.

In the magnetoresistive element 1G, torque corresponding to the upward spin or the downward spin is generated according to the direction of the current by the GMR effect, and the torque acts on the magnetic layer 12. As a result, the magnetization of the magnetic layer 12 changes, the magnetization acts on the magnetization of the storage layer 21, and the magnetization direction of the storage layer 21 changes.

### 1-4-7. Seventh Modification

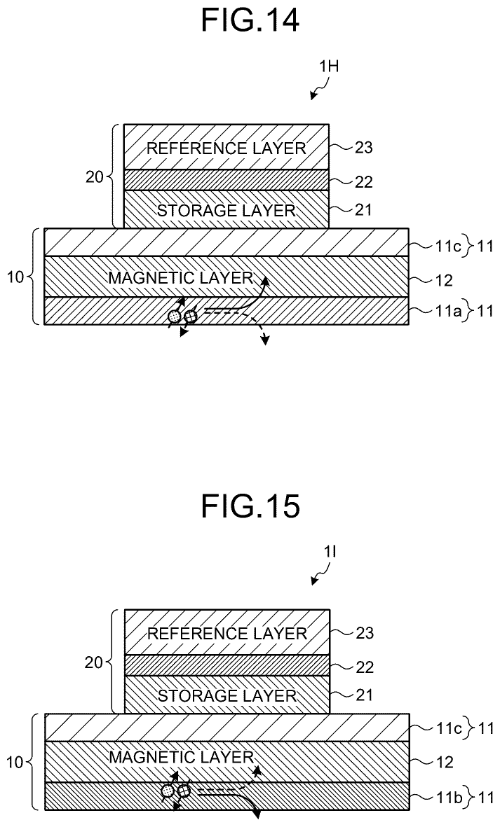

As illustrated in FIG. 14, the magnetoresistive element 1H according to the seventh modification includes a first laminated body 10 and the second laminated body 20 according to the above-described embodiment. The first laminated body 10 includes an upper non-magnetic metal layer 11, the magnetic layer 12 according to the above-described embodiment, and a lower non-magnetic metal layer 11. The upper non-magnetic metal layer 11 includes not a spin injection layer but only the metal layer (non-spin-injection metal layer) 11c that does not inject a spin into the storage layer 21. The metal layer 11c is made of, for example, a heavy metal such as Cu. The lower non-magnetic metal layer 11 includes only the first spin injection layer 11a. Note that the magnetic layer 12 is sandwiched between the metal layer 11c and the first spin injection layer 11a.

In the magnetoresistive element 1H, an upward spin or a downward spin enters the magnetic layer 12 according to the direction of the current. The spin orbit torque due to the upward spin or the downward spin acts on the magnetization of the magnetic layer 12. Furthermore, in the magnetic layer 12, torque corresponding to the upward spin or the downward spin is generated by the GMR effect, and the torque acts on the magnetic layer 12. By such actions, the magnetization of the magnetic layer 12 changes, the magnetization acts on the magnetization of the storage layer 21, and the magnetization direction of the storage layer 21 changes.

### 1-4-8. Eighth Modification

As illustrated in FIG. 15, the magnetoresistive element 1I according to the eighth modification includes a first laminated body 10 and the second laminated body 20 according to the above-described embodiment. The first laminated body 10 includes an upper non-magnetic metal layer 11, the magnetic layer 12 according to the above-described embodiment, and a lower non-magnetic metal layer 11. The upper non-magnetic metal layer 11 includes not a spin injection layer but only the metal layer (non-spin-injection metal layer) 11c that does not inject a spin into the storage layer 21. The metal layer 11c is made of, for example, a heavy metal such as Cu. The lower non-magnetic metal layer 11 includes only the second spin injection layer 11b. Note that the magnetic layer 12 is sandwiched between the metal layer 11c and the second spin injection layer 11b.

In the magnetoresistive element 1I, as in the seventh modification, an upward spin or a downward spin enters the magnetic layer 12 according to the direction of the current. The spin orbit torque due to the upward spin or the downward spin acts on the magnetization of the magnetic layer 12. Furthermore, in the magnetic layer 12, torque corresponding to the upward spin or the downward spin is generated by the GMR effect, and the torque acts on the magnetic layer 12. By such actions, the magnetization of the magnetic layer 12 changes, the magnetization acts on the magnetization of the storage layer 21, and the magnetization direction of the storage layer 21 changes.

### 1-4-9. Ninth Modification

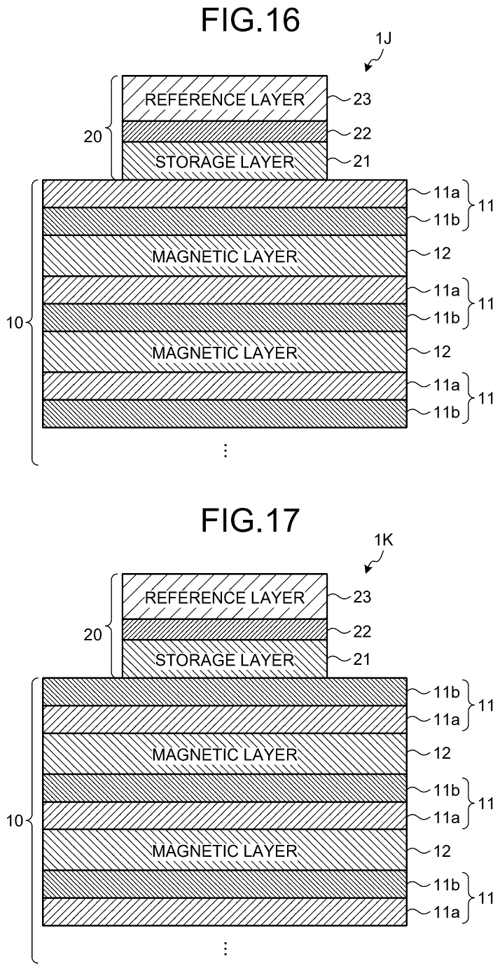

As illustrated in FIG. 16, the magnetoresistive element 1J according to the ninth modification includes a first laminated body 10 and the second laminated body 20 according to the above-described embodiment. The first laminated body 10 is configured by alternately laminating the non-magnetic metal layers 11 and the magnetic layers 12 a plurality of times. The non-magnetic metal layer 11 includes the first spin injection layer 11a and the second spin injection layer 11b. In the non-magnetic metal layer 11, the first spin injection layer 11a is located on the upper layer side, that is, on the storage layer 21 side of the second spin injection layer 11b. Note that the magnetic layer 12 is sandwiched between the second spin injection layer 11b and the first spin injection layer 11a. In such a magnetoresistive element 1J, writing and reading basically similar to those in the above-described embodiment are performed.

### 1-4-10. Tenth Modification

As illustrated in FIG. 17, the magnetoresistive element 1K according to the tenth modification includes a first laminated body 10 and the second laminated body 20 according to the above-described embodiment. The first laminated body 10 is configured by alternately laminating the non-magnetic metal layers 11 and the magnetic layers 12 a plurality of times. The non-magnetic metal layer 11 includes the first spin injection layer 11a and the second spin injection layer 11b. In the non-magnetic metal layer 11, the second spin injection layer 11b is located on the upper layer side, that is, on the storage layer 21 side of the first spin injection layer 11a. Note that the magnetic layer 12 is sandwiched between the first spin injection layer 11a and the second spin injection layer 11b. In such a magnetoresistive element 1K, writing and reading basically similar to those in the above-described embodiment are performed.

### 1-4-11. Eleventh Modification

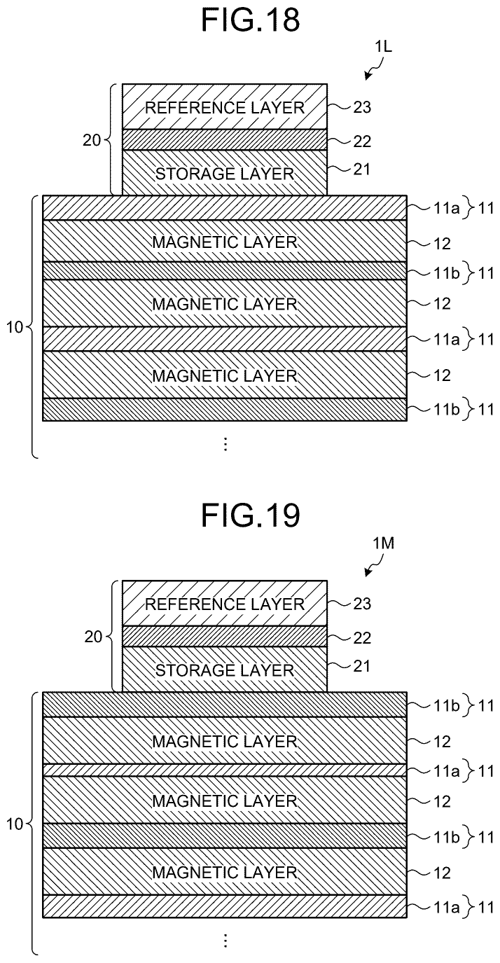

As illustrated in FIG. 18, the magnetoresistive element 1L according to the eleventh modification includes a first laminated body 10 and the second laminated body 20 according to the above-described embodiment. The first laminated body 10 is configured by alternately laminating the non-magnetic metal layers 11 and the magnetic layers 12 a plurality of times. Specifically, the second spin injection layer 11b, the magnetic layer 12, the first spin injection layer 11a, the magnetic layer 12, the second spin injection layer 11b, the magnetic layer 12, and the first spin injection layer 11a are laminated in this order. Note that the magnetic layer 12 is sandwiched between the first spin injection layer 11a and the second spin injection layer 11b. In such a magnetoresistive element 1L, writing and reading basically similar to those in the above-described embodiment are performed.

### 1-4-12. Twelfth Modification

As illustrated in FIG. 19, the magnetoresistive element 1M according to the twelfth modification includes a first laminated body 10 and the second laminated body 20 according to the above-described embodiment. The first laminated body 10 is configured by alternately laminating the non-magnetic metal layers 11 and the magnetic layers 12 a plurality of times. Specifically, the first spin injection layer 11a, the magnetic layer 12, the second spin injection layer 11b, the magnetic layer 12, the first spin injection layer 11a, the magnetic layer 12, and the second spin injection layer 11b are laminated in this order. Note that the magnetic layer 12 is sandwiched between the first spin injection layer 11a and the second spin injection layer 11b. In such a magnetoresistive element 1M, writing and reading basically similar to those in the above-described embodiment are basically performed.

### 1-4-13. Thirteenth Modification

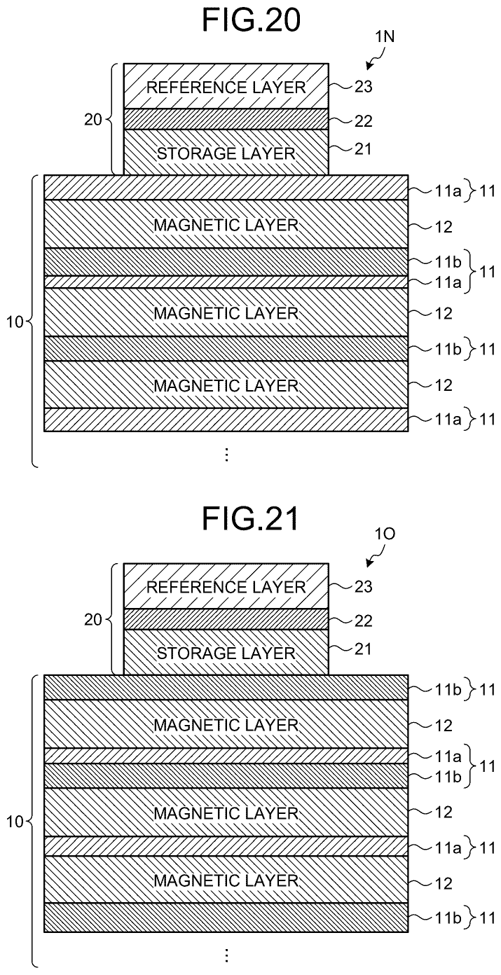

As illustrated in FIG. 20, the magnetoresistive element 1N according to the thirteenth modification includes a first laminated body 10 and the second laminated body 20 according to the above-described embodiment. The first laminated body 10 is configured by alternately laminating the non-magnetic metal layers 11 and the magnetic layers 12 a plurality of times. Specifically, the first spin injection layer 11a, the magnetic layer 12, the second spin injection layer 11b, the magnetic layer 12, the first spin injection layer 11a, the second spin injection layer 11b, the magnetic layer 12, and the first spin injection layer 11a are laminated in this order. Note that the magnetic layer 12 is sandwiched between the first spin injection layer 11a and the second spin injection layer 11b. In such a magnetoresistive element IN, writing and reading basically similar to those in the above-described embodiment are performed.

### 1-4-14. Fourteenth Modification

As illustrated in FIG. 21, the magnetoresistive element 1O according to the fourteenth modification includes a first laminated body 10 and the second laminated body 20 according to the above-described embodiment. The first laminated body 10 is configured by alternately laminating the non-magnetic metal layers 11 and the magnetic layers 12 a plurality of times. Specifically, the second spin injection layer 11b, the magnetic layer 12, the first spin injection layer 11a, the magnetic layer 12, the second spin injection layer 11b, the first spin injection layer 11a, the magnetic layer 12, and the second spin injection layer 11b are laminated in this order. Note that the magnetic layer 12 is sandwiched between the first spin injection layer 11a and the second spin injection layer 11b. In such a magnetoresistive element 1O, writing and reading basically similar to those in the above-described embodiment are performed.

### 1-5. Action and Effect

As described above, according to the embodiment, any one of the magnetoresistive elements 1A to 1O includes the first laminated body 10, the storage layer 21 laminated on the first laminated body 10 and having a variable magnetization direction, the non-magnetic layer 22 laminated on the storage layer 21, and the reference layer 23 laminated on the non-magnetic layer 22 and having a fixed magnetization direction, in which the first laminated body 10 includes the magnetic layer 12 having a variable magnetization direction and the non-magnetic metal layer 11 laminated on the magnetic layer 12 (see FIG. 1 and the like). As a result, it is possible to suppress a write current by utilizing a magnetic material having higher spin conversion efficiency than a non-magnetic material for the first laminated body 10, and thus, it is possible to reduce power consumption.

In addition, the non-magnetic metal layer 11 may include the first spin injection layer 11a having the spin Hall angle of the first sign and the second spin injection layer 11b having the spin Hall angle of the second sign different from the first sign (see FIG. 1 and the like). As a result, it is possible to suppress deterioration in the spin orbit torque (SOT) by suppressing cancellation between the upward spins or between the downward spins, so that the write current can be further suppressed.

Furthermore, the first spin injection layer 11a or the second spin injection layer 11b may be provided to be in contact with the storage layer 21 (see FIG. 1 and the like). Even with such a configuration, the write current can be suppressed.

Furthermore, the non-magnetic metal layer 11 may be the first spin injection layer 11a having the spin Hall angle of the first sign (see FIGS. 9 and 11). Even with such a configuration, the write current can be suppressed.

In addition, the first laminated body 10 may further include the second non-magnetic metal layer 11 in which the magnetic layer 12 is laminated in addition to the first spin injection layer 11a, and the second non-magnetic metal layer 11 may be the second spin injection layer 11b having the spin Hall angle of the second sign different from the first sign (see FIGS. 10 and 12). Even with such a configuration, the write current can be suppressed.

Furthermore, the non-magnetic metal layer 11 may be the metal layer 11c that does not inject a spin into the storage layer 21 (see FIG. 13). Even with such a configuration, the write current can be suppressed.

In addition, the first laminated body 10 may further include the second non-magnetic metal layer 11 in which the magnetic layer 12 is laminated in addition to the non-spin-injection metal layer 11c, and the second non-magnetic metal layer 11 may be a spin injection layer having the spin Hall angle of the first sign (See FIGS. 14 and 15). Even with such a configuration, the write current can be suppressed.

Furthermore, the first laminated body 10 may include a plurality of magnetic layers 12 and a plurality of non-magnetic metal layers 11, and the magnetic layers 12 and the non-magnetic metal layers 11 may be alternately laminated (see FIGS. 1 to 8 and FIGS. 16 to 21). Even with such a configuration, the write current can be suppressed.

Furthermore, the plurality of magnetic layers 12 may be antiferromagnetically coupled to each other. As a result, since spin conversion efficiency can be increased, the write current can be further suppressed.

In addition, each of the plurality of non-magnetic metal layers 11 may include the first spin injection layer 11a having the spin Hall angle of the first sign and the second spin injection layer 11b having the spin Hall angle of the second sign different from the first sign (see FIGS. 16 and 17). Even with such a configuration, the write current can be suppressed.

In addition, the plurality of non-magnetic metal layers 11 may be configured such that the lamination order of the first spin injection layer 11a and the second spin injection layer 11b is the same (see FIGS. 16 and 17). Even with such a configuration, the write current can be suppressed.

In addition, each of the plurality of non-magnetic metal layers 11 may include the first spin injection layer 11a having the spin Hall angle of the first sign or the second spin injection layer 11b having the spin Hall angle of the second sign different from the first sign, and each of the plurality of magnetic layers 12 may be sandwiched between the first spin injection layer 11a and the second spin injection layer 11b (see FIGS. 18 and 19). Even with such a configuration, the write current can be suppressed.

In addition, at least one of the plurality of non-magnetic metal layers 11 may include the first spin injection layer 11a having the spin Hall angle of the first sign and the second spin injection layer 11b having the spin Hall angle of the second sign different from the first sign (see FIGS. 20 and 21). Even with such a configuration, the write current can be suppressed.

Furthermore, the non-magnetic layer 22 may be a tunnel barrier layer. Even with such a configuration, the write current can be suppressed.

In addition, any one of the magnetoresistive elements 1A to 1O may include two terminals T1 and T2 provided in the first laminated body 10 and one terminal T3 provided in the reference layer 23. Even with such a configuration, the write current can be suppressed.

### 2. Storage Device (Application Example)

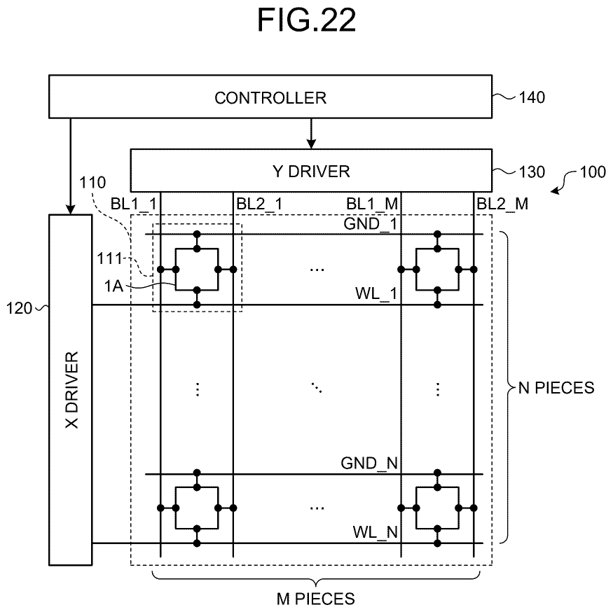

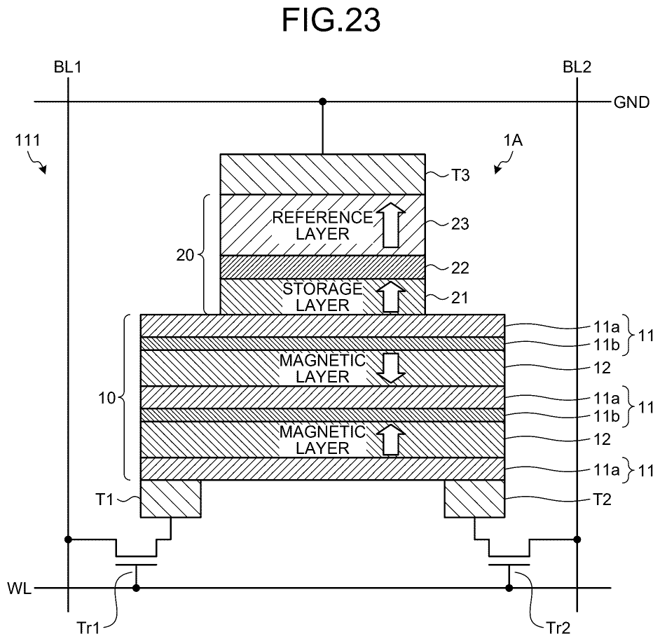

A storage device 100 to which any one of the magnetoresistive elements 1A to 1O according to the above-described embodiment (including modifications) is applied will be described with reference to FIGS. 22 and 23. FIG. 22 is a diagram illustrating a configuration example of the storage device 100 according to an application example. The storage device 100 is an example of a storage device that stores information using a magnetization direction of a magnetic material. FIG. 23 is a diagram illustrating a configuration example of a memory cell 111 according to the application example. In the example of FIG. 23, the memory cell 111 which is a magnetic memory cell for one-bit is illustrated.

As illustrated in FIG. 22, the storage device 100 according to a second embodiment includes a memory cell array 110, an X driver 120, a Y driver 130, and a controller 140.

The memory cell array 110 includes a plurality of the memory cells 111. The memory cells 111 are provided in a matrix configuration, and each of the memory cells 111 includes the magnetoresistive element 1A. The X driver 120 is connected to a plurality of word lines WL (N), the Y driver 130 is connected to a plurality of bit lines BL (N_N), and the drivers function as a write unit and a read unit. The controller 150 performs processing of a write/read command, control of data input/output, and the like. For example, the controller 150 controls writing and reading of data in response to a command (a command such as writing and reading).

As illustrated in FIG. 23, the memory cell 111 includes the magnetoresistive element 1A, a first transistor Tr1, and a second transistor Tr2. A first bit line BL1, a second bit line BL2, a word line WL, and a ground line GND are connected to the memory cell 111. The first bit line BL1 and the second bit line BL2 are wired to extend in a column direction, and the word line WL and the ground line GND are wired to extend in a row direction. In the memory cell 111, an element other than the magnetoresistive element 1A, for example, an element of any one of the magnetoresistive elements 1B to 1O may be used.

When writing data into such a memory cell 111, a difference is provided in level setting (potential) between the first bit line BL1 and the second bit line BL2. As a result, a write current is introduced into the first laminated body 10, the magnetization direction of the storage layer 21 is reversed, and data is written. Note that a write scheme is basically the same as that of the above-described embodiment.

In addition, when reading data from the memory cell 111, after the word line WL is set to an active level, one of the first transistor Tr1 and the second transistor Tr2 is turned on and is set to a high level, and the other one is opened. As a result, a read current flows from the lower surface of the first laminated body 10 to the ground line GND via the first laminated body 10 and the second laminated body 20, and data is read from a resistance value of the current path. Note that a read scheme is basically similar to that of the above-described embodiment.

In the storage device 100 configured as described above as well, by using any one of the magnetoresistive elements 1A to 1O described above, it is possible to suppress the write current, and to realize low power consumption writing, that is, reduction in power consumption.

### 3. Electronic Apparatus (Application Example)

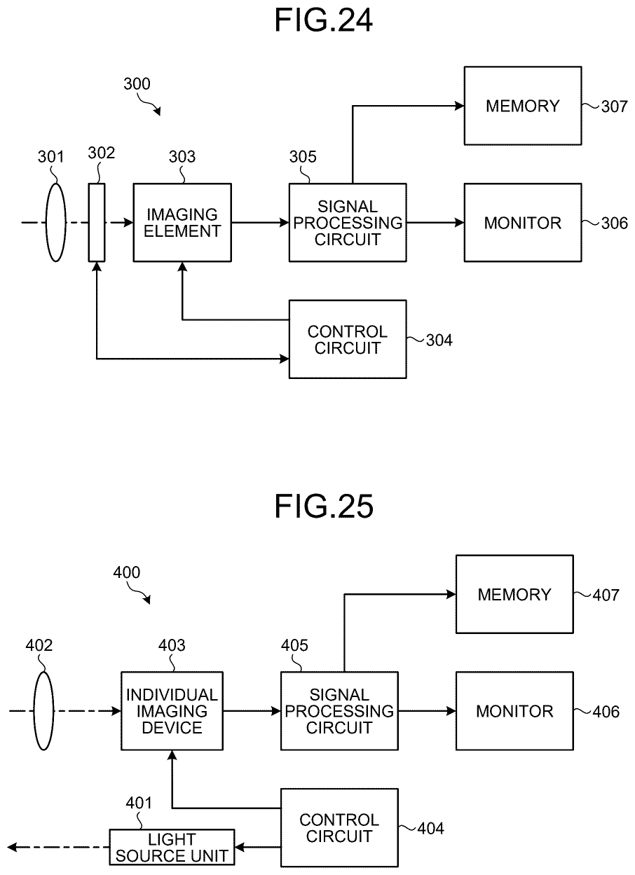

As an electronic apparatus to which the above storage device 100 is applied, an imaging device 300, a distance measurement device 400, and a game apparatus 900 will be described with reference to FIGS. 24 to 27. For example, each of the imaging device 300, the distance measurement device 400, and the game apparatus 900 uses the above storage device 100 as a memory.

### 3-1. Imaging Device

The imaging device 300 to which the above storage device 100 is applied will be described with reference to FIG. 26. FIG. 26 is a diagram illustrating an example of a schematic configuration of the imaging device 300 according to the application example. The imaging device 300 is an example of the electronic apparatus to which the above storage device 100 is applied. Examples of the imaging device 300 include electronic devices such as a digital still camera, a video camera, a smartphone having an imaging function, a mobile phone, and the like.

As illustrated in FIG. 26, the imaging device 300 includes an optical system 301, a shutter device 302, an imaging element 303, a control circuit (drive circuit) 304, a signal processing circuit 305, a monitor 306, and a memory 307. The imaging device 300 can capture a still image and a moving image.

The optical system 301 includes one or a plurality of lenses. The optical system 301 guides light (incident light) from a subject to the imaging element 303 and forms an image on a light receiving surface of the imaging element 303.

The shutter device 302 is disposed between the optical system 301 and the imaging element 303. The shutter device 302 controls a light irradiation period and a light shielding period with respect to the imaging element 303 according to the control of the control circuit 304.

The imaging element 303 accumulates signal charges for a certain period according to light formed on the light receiving surface via the optical system 301 and the shutter device 302. The signal charges accumulated in the imaging element 303 is transferred in accordance with a drive signal (timing signal) supplied from the control circuit 304.

The control circuit 304 outputs the drive signal for controlling a transfer operation of the imaging element 303 and a shutter operation of the shutter device 302 to drive the imaging element 303 and the shutter device 302.

The signal processing circuit 305 performs various types of signal processing on the signal charges output from the imaging element 303. An image (image data) obtained by performing the signal processing by the signal processing circuit 305 is supplied to the monitor 306 and also supplied to the memory 307.

The monitor 306 displays a moving image or a still image captured by the imaging element 303 based on the image data supplied from the signal processing circuit 305. As the monitor 306, for example, a panel type display device such as a liquid crystal panel or an organic electro luminescence (EL) panel is used.

The memory 307 stores the image data supplied from the signal processing circuit 305, that is, image data of the moving image or the still image captured by the imaging element 303. The memory 307 corresponds to the above storage device 100.

Also in the imaging device 300 configured in this manner, by using the above-described storage device 100 as the memory 307, it is possible to suppress the write current, and to realize low power consumption writing, that is, reduction in power consumption.

### 3-2. Distance Measurement Device

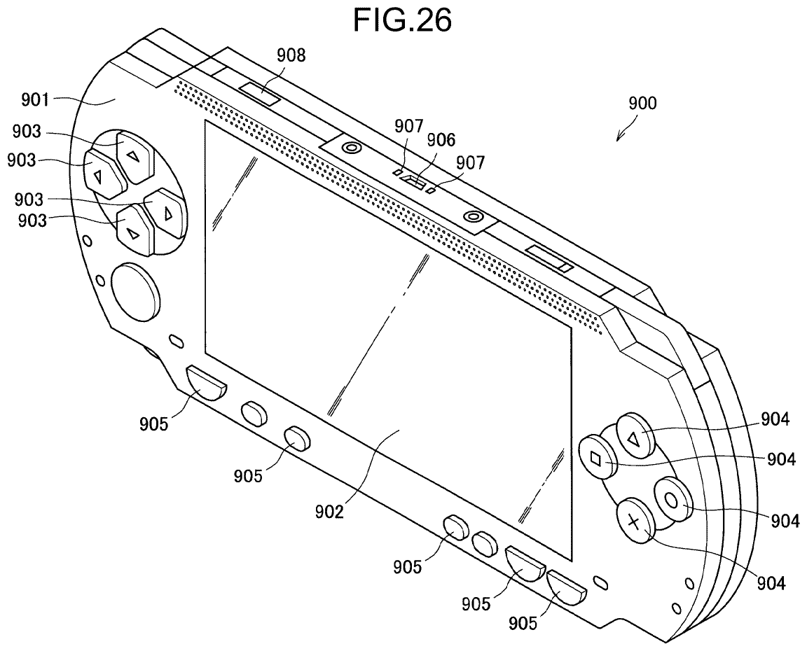

The distance measurement device 400 to which the above storage device 100 is applied will be described with reference to FIG. 25. FIG. 25 is a diagram illustrating an example of a schematic configuration of the distance measurement device 400 according to the application example. The distance measurement device 400 is an example of the electronic apparatus to which the above storage device 100 is applied.

As illustrated in FIG. 25, the distance measurement device (distance image sensor) 400 includes a light source unit 401, an optical system 402, a solid-state imaging device (imaging element) 403, a control circuit (drive circuit) 404, a signal processing circuit 405, a monitor 406, and a memory 407. The distance measurement device 400 can acquire a distance image according to a distance to a subject by projecting light from the light source unit 401 toward the subject and receiving light (modulated light or pulsed light) reflected from a surface of the subject.

The light source unit 401 projects light toward the subject. As the light source unit 401, for example, a vertical cavity surface emitting laser (VCSEL) array that emits laser light as a surface light source or a laser diode array in which laser diodes are arrayed on a line is used. Note that the laser diode array is supported by a predetermined drive unit (not illustrated), and is scanned in a direction perpendicular to the array direction of the laser diodes.

The optical system 402 includes one or a plurality of lenses. The optical system 402 guides light (incident light) from the subject to the solid-state imaging device 403 to form an image on a light receiving surface (sensor unit) of the solid-state imaging device 403.

The solid-state imaging device 403 stores signal charges according to the light of the image formed on the light receiving surface via the optical system 402. A distance signal indicating the distance obtained from a light reception signal (APD OUT) output from the solid-state imaging device 403 is supplied to the signal processing circuit 405. As the solid-state imaging device 403, for example, a solid-state imaging element such as an image sensor is used.

The control circuit 404 outputs a drive signal (control signal) for controlling operations of the light source unit 401, the solid-state imaging device 403, and the like to drive the light source unit 401, the solid-state imaging device 403, and the like.

The signal processing circuit 405 performs various types of signal processing on the distance signal supplied from the solid-state imaging device 403. For example, the signal processing circuit 405 performs image processing (for example, histogram processing, peak detection processing, and the like) of constructing the distance image on the basis of the distance signal. An image (image data) obtained by performing the signal processing by the signal processing circuit 405 is supplied to the monitor 406 and also supplied to the memory 407.

The monitor 406 displays the distance image captured by the imaging element 303 on the basis of the image data supplied from the signal processing circuit 405. As the monitor 406, for example, a panel type display device such as a liquid crystal panel or an organic EL panel is used.

The memory 407 stores the image data supplied from the signal processing circuit 405, that is, the image data of the distance image captured by the imaging element 303. The memory 407 corresponds to the above storage device 100.

Also in the distance measurement device 400 configured in this manner, by using the above-described storage device 100 as the memory 407, it is possible to suppress the write current, and to realize low power consumption writing, that is, reduction in power consumption.

### 3-3. Game Device

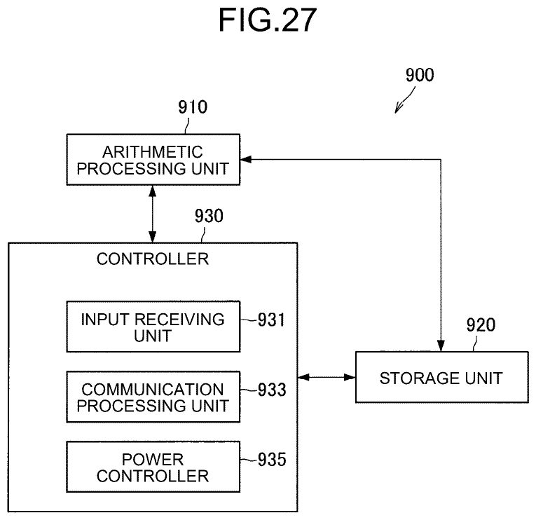

The game device 900 to which the above storage device 100 is applied will be described with reference to FIGS. 26 and 27. FIG. 26 is a perspective view (external perspective view) illustrating an example of the schematic configuration of the game device 900 according to the application example. FIG. 27 is a block diagram illustrating an example of the schematic configuration of the game device 900 according to the application example. The game device 900 is an example of the electronic apparatus to which the above storage device 100 is applied.

As illustrated in FIG. 26, for example, the game device 900 has an appearance in which each component is disposed inside and outside an outer casing 901 formed in a horizontally long flat shape.

On the front surface of the outer casing 901, a display panel 902 is provided at the center thereof in the longitudinal direction. Further, operation keys 903 and operation keys 904 are provided on the left and right sides of the display panel 902, respectively, spaced apart from each other in the circumferential direction. An operation key 905 is provided at a lower end of the front surface of the outer casing 901. The operation keys 903, 904, and 905 function as direction keys, determination keys, or the like, and are used for selection of menu items displayed on the display panel 902, progress of a game, or the like.

On the upper surface of the outer casing 901, a connection terminal 906 for connecting an external device, a power supply terminal 907, a light receiving window 908 for performing infrared communication with the external device, and the like are provided.

As illustrated in FIG. 27, the game device 900 includes an arithmetic processing unit 910 including a central processing unit (CPU), a storage unit 920 that stores various types of information, and a controller 930 that controls each configuration of the game device 900. Power is supplied to the arithmetic processing unit 910 and the controller 930 from, for example, a battery (not illustrated) or the like.

The arithmetic processing unit 910 generates a menu screen for allowing a user to set various types of information or select an application. In addition, the arithmetic processing unit 910 executes the application selected by the user.

The storage unit 920 stores various types of information set by the user. The storage unit 920 corresponds to the above storage device 100.

The controller 930 includes an input receiving unit 931, a communication processing unit 933, and a power controller 935. The input receiving unit 931 detects, for example, the states of the operation keys 903, 904, and 905. Furthermore, the communication processing unit 933 performs communication processing with an external device. The power controller 935 controls power supplied to each unit of the game device 900.

Also in the game device 900 configured in this manner, by using the above-described storage device 100 as the storage unit 920, it is possible to suppress the write current, and to realize low power consumption writing, that is, reduction in power consumption.

It is noted that the above storage device 100 may be mounted on the same semiconductor chip together with a semiconductor circuit forming an arithmetic device or the like to form a semiconductor device (System-on-a-Chip: SoC).

Furthermore, the above storage device 100 can be mounted on various electronic devices on which a memory (storage unit) can be mounted as described above. For example, the storage device 100 may be mounted on various electronic devices such as a hard disk drive (HDD), a notebook personal computer (PC), a mobile device (for example, a smartphone, a tablet PC, or the like), a personal digital assistant (PDA), a wearable device, and a music device in addition to the imaging device 300 and the game device 900. For example, the above storage device 100 is used as various memories such as a storage.

### 4. Other Embodiments

The configurations according to the above embodiments may be implemented in various different forms other than the above embodiments. For example, the configurations are not limited to the above-described examples, and may be various modes. Further, for example, information including configurations, processing procedures, specific names, and various types of data and parameters illustrated in the document and the drawings can be freely and selectively changed unless otherwise specified.

In addition, each component of each device illustrated in the drawings is functionally conceptual, and is not necessarily physically configured as illustrated in the drawings. That is, a specific form of distribution and integration of each device is not limited to the illustrated form, and all or a part thereof can be functionally or physically distributed and integrated in any unit according to various loads, usage conditions, and the like.

In addition, the above-described embodiments (or modifications) can be appropriately combined within a range that does not contradict processing contents. Furthermore, the effects described in the present specification are merely examples and are not limited, and other effects may be obtained.

### 5. Appendix

Note that the present technology can also have the following configurations.
(1)

A magnetoresistive element comprising:
a laminated body;
a storage layer laminated on the laminated body and having
a variable magnetization direction;
a non-magnetic layer laminated on the storage layer; and
a reference layer laminated on the non-magnetic layer and having a fixed magnetization direction, wherein
the laminated body includes
a magnetic layer having a variable magnetization direction, and
a non-magnetic metal layer laminated on the magnetic layer.
(2)

The magnetoresistive element according to (1), wherein
the non-magnetic metal layer includes
a first spin injection layer having a spin Hall angle of a first sign, and
a second spin injection layer having a spin Hall angle of a second sign different from the first sign.
(3)

The magnetoresistive element according to (2), wherein
the first spin injection layer or the second spin injection layer is provided to be in contact with the storage layer.
(4)

The magnetoresistive element according to (1), wherein
the non-magnetic metal layer is a first spin injection layer having a spin Hall angle of a first sign.
(5)

The magnetoresistive element according to (4), wherein
the laminated body further includes a second non-magnetic metal layer in which the magnetic layer is laminated, and
the second non-magnetic metal layer is a second spin injection layer having a spin Hall angle of a second sign different from the first sign.
(6)

The magnetoresistive element according to (1), wherein
the non-magnetic metal layer is a metal layer configured not to inject a spin to the storage layer.
(7)

The magnetoresistive element according to (6), wherein
the laminated body further includes a second non-magnetic metal layer in which the magnetic layer is laminated, and
the second non-magnetic metal layer is a spin injection layer having a spin Hall angle of a first sign.
(8)

The magnetoresistive element according to (1), wherein
the laminated body includes
a plurality of the magnetic layers, and
a plurality of the non-magnetic metal layers, and
the magnetic layer and the non-magnetic metal layer are alternately laminated.
(9)

The magnetoresistive element according to (8), wherein
the plurality of the magnetic layers are antiferromagnetically coupled to each other.
(10)

The magnetoresistive element according to (8) or (9), wherein
each of the plurality of the non-magnetic metal layers includes
a first spin injection layer having a spin Hall angle of a first sign, and
a second spin injection layer having a spin Hall angle of a second sign different from the first sign.
(11)

The magnetoresistive element according to (10), wherein
the plurality of the non-magnetic metal layers are configured such that the first spin injection layer and the second spin injection layer have the same lamination order.
(12)

The magnetoresistive element according to (8) or (9), wherein
each of the plurality of the non-magnetic metal layers includes a first spin injection layer having a spin Hall angle of a first sign or a second spin injection layer having a spin Hall angle of a second sign different from the first sign, and
each of the plurality of the magnetic layers is sandwiched between the first spin injection layer and the second spin injection layer.
(13)

The magnetoresistive element according to (12), wherein
at least one of the plurality of the non-magnetic metal layers includes
the first spin injection layer having a spin Hall angle of a first sign, and
the second spin injection layer having a spin Hall angle of a second sign different from the first sign.
(14)

The magnetoresistive element according to any one of (1) to (13), wherein
the non-magnetic layer is a tunnel barrier layer.
(15)

The magnetoresistive element according to any one of (1) to (14), further comprising:
two terminals provided in the laminated body; and
one terminal provided in the reference layer.
(16)

A storage device comprising:
a plurality of magnetoresistive elements, wherein
each of the plurality of magnetoresistive elements includes
a laminated body,
a storage layer laminated on the laminated body and having a variable magnetization direction,
a non-magnetic layer laminated on the storage layer, and
a reference layer laminated on the non-magnetic layer and having a fixed magnetization direction, and
the laminated body includes
a magnetic layer having a variable magnetization direction, and
a non-magnetic metal layer laminated on the magnetic layer.
(17)

An electronic apparatus comprising:
a storage device, wherein
the storage device includes
a plurality of magnetoresistive elements,
each of the plurality of magnetoresistive elements includes
a laminated body,
a storage layer laminated on the laminated body and having a variable magnetization direction,
a non-magnetic layer laminated on the storage layer, and
a reference layer laminated on the non-magnetic layer and having a fixed magnetization direction, and
the laminated body includes
a magnetic layer having a variable magnetization direction, and
a non-magnetic metal layer laminated on the magnetic layer.
(18)

A storage device including the magnetoresistive element according to any one of (1) to (15).
(19)

An electronic apparatus including the storage device according to (18).

### REFERENCE SIGNS LIST

1A MAGNETORESISTIVE ELEMENT
1B MAGNETORESISTIVE ELEMENT
1C MAGNETORESISTIVE ELEMENT
1D MAGNETORESISTIVE ELEMENT
1E MAGNETORESISTIVE ELEMENT
1F MAGNETORESISTIVE ELEMENT
1G MAGNETORESISTIVE ELEMENT
1H MAGNETORESISTIVE ELEMENT
1I MAGNETORESISTIVE ELEMENT
1J MAGNETORESISTIVE ELEMENT
1K MAGNETORESISTIVE ELEMENT
1L MAGNETORESISTIVE ELEMENT
1M MAGNETORESISTIVE ELEMENT
1N MAGNETORESISTIVE ELEMENT
1O MAGNETORESISTIVE ELEMENT
10 FIRST LAMINATED BODY
11a FIRST SPIN INJECTION LAYER
11b SECOND SPIN INJECTION LAYER
11c METAL LAYER
11 NON-MAGNETIC METAL LAYER
12 MAGNETIC LAYER
20 SECOND LAMINATED BODY
21 STORAGE LAYER
22 NON-MAGNETIC LAYER
23 REFERENCE LAYER
30 LAMINATE STRUCTURE BODY
31 MAGNETIC LAYER
32 NON-MAGNETIC METAL LAYER
50 CONTROLLER
100 STORAGE DEVICE
300 IMAGING DEVICE
400 DISTANCE MEASUREMENT DEVICE
900 GAME DEVICE
T1 TERMINAL
T2 TERMINAL
T3 TERMINAL

1. A magnetoresistive element comprising:
a laminated body;
a storage layer laminated on the laminated body and having a variable magnetization direction;
a non-magnetic layer laminated on the storage layer; and
a reference layer laminated on the non-magnetic layer and having a fixed magnetization direction, wherein
the laminated body includes
a magnetic layer having a variable magnetization direction, and
a non-magnetic metal layer laminated on the magnetic layer.

2. The magnetoresistive element according to claim 1, wherein
the non-magnetic metal layer includes
a first spin injection layer having a spin Hall angle of a first sign, and
a second spin injection layer having a spin Hall angle of a second sign different from the first sign.

3. The magnetoresistive element according to claim 2, wherein
the first spin injection layer or the second spin injection layer is provided to be in contact with the storage layer.

4. The magnetoresistive element according to claim 1, wherein
the non-magnetic metal layer is a first spin injection layer having a spin Hall angle of a first sign.

5. The magnetoresistive element according to claim 4, wherein
the laminated body further includes a second non-magnetic metal layer in which the magnetic layer is laminated, and
the second non-magnetic metal layer is a second spin injection layer having a spin Hall angle of a second sign different from the first sign.

6. The magnetoresistive element according to claim 1, wherein
the non-magnetic metal layer is a metal layer configured not to inject a spin to the storage layer.

7. The magnetoresistive element according to claim 6, wherein
the laminated body further includes a second non-magnetic metal layer in which the magnetic layer is laminated, and
the second non-magnetic metal layer is a spin injection layer having a spin Hall angle of a first sign.

8. The magnetoresistive element according to claim 1, wherein
the laminated body includes
a plurality of the magnetic layers, and
a plurality of the non-magnetic metal layers, and
the magnetic layer and the non-magnetic metal layer are alternately laminated.

9. The magnetoresistive element according to claim 8, wherein
the plurality of the magnetic layers are antiferromagnetically coupled to each other.

10. The magnetoresistive element according to claim 8, wherein
each of the plurality of the non-magnetic metal layers includes
a first spin injection layer having a spin Hall angle of a first sign, and
a second spin injection layer having a spin Hall angle of a second sign different from the first sign.

11. The magnetoresistive element according to claim 10, wherein
the plurality of the non-magnetic metal layers are configured such that the first spin injection layer and the second spin injection layer have the same lamination order.

12. The magnetoresistive element according to claim 8, wherein
each of the plurality of the non-magnetic metal layers includes a first spin injection layer having a spin Hall angle of a first sign or a second spin injection layer having a spin Hall angle of a second sign different from the first sign, and
each of the plurality of the magnetic layers is sandwiched between the first spin injection layer and the second spin injection layer.

13. The magnetoresistive element according to claim 12, wherein
at least one of the plurality of the non-magnetic metal layers includes
the first spin injection layer having a spin Hall angle of a first sign, and
the second spin injection layer having a spin Hall angle of a second sign different from the first sign.

14. The magnetoresistive element according to claim 1, wherein
the non-magnetic layer is a tunnel barrier layer.

15. The magnetoresistive element according to claim 1, further comprising:
two terminals provided in the laminated body; and
one terminal provided in the reference layer.

16. A storage device comprising:
a plurality of magnetoresistive elements, wherein
each of the plurality of magnetoresistive elements includes
a laminated body,
a storage layer laminated on the laminated body and having a variable magnetization direction,
a non-magnetic layer laminated on the storage layer, and
a reference layer laminated on the non-magnetic layer and having a fixed magnetization direction, and
the laminated body includes
a magnetic layer having a variable magnetization direction, and
a non-magnetic metal layer laminated on the magnetic layer.

17. An electronic apparatus comprising:
a storage device, wherein
the storage device includes
a plurality of magnetoresistive elements,
each of the plurality of magnetoresistive elements includes
a laminated body,
a storage layer laminated on the laminated body and having a variable magnetization direction,
a non-magnetic layer laminated on the storage layer, and
a reference layer laminated on the non-magnetic layer and having a fixed magnetization direction, and
the laminated body includes
a magnetic layer having a variable magnetization direction, and
a non-magnetic metal layer laminated on the magnetic layer.
